(19) United States
(12) Patent Application Publication
(10) Pub. No.: US 2013/0332099 A1
(43) Pub. Date: Dec. 12, 2013

(54) CURRENT MEASUREMENT SYSTEM

(71) Applicants: CHIH-SUNG LAI, NEW TAIPEI CITY (TW); WEI-YAO CHENG, TAIPEI CITY (TW)

(72) Inventors: CHIH-SUNG LAI, NEW TAIPEI CITY (TW); WEI-YAO CHENG, TAIPEI CITY (TW)

(73) Assignee: ASKEY COMPUTER CORP.

(21) Appl. No.: 13/604,762

(22) Filed: Sep. 6, 2012

(30) Foreign Application Priority Data
Jun. 7, 2012 (TW) 101120469

(51) Int. Cl. G06F 19/00; G01R 19/00

(52) U.S. Cl. 702/104

(57) ABSTRACT

A current measurement system precisely measures a current generated by a circuit under test. The current measurement system has a sampling unit serially connected to the circuit under test for the acquisition of a first voltage. The first voltage is amplified and transformed to a second voltage by an amplifying unit. A noise suppression unit filters analog voltage noises produced from the second voltage and transforms the second voltage to a third voltage. The third voltage is converted into a voltage signal in a digital format by a conversion unit. The voltage signal undergoes calibrations and turns into a measure signal by using a processing unit and a stored calibration linear equation. The measure signal indicates a precise measurement of the current. A memory unit stores a gradient and a bias voltage level required for the calibration linear equation.

### CROSS-REFERENCE TO RELATED APPLICATION

This non-provisional application claims priority under 35 U.S.C. §119(a) on Patent Application No(s). 101120469 filed in Taiwan, R.O.C. on Jun. 7, 2012, the entire contents of which are hereby incorporated by reference.

### FIELD OF TECHNOLOGY

The present invention relates to a current measurement system, in particular to the current measurement system capable of measuring a current generated by a circuit under test precisely.

### BACKGROUND

In conventional current measuring methods, measuring meters such as multimeters and ammeters are generally used for measuring current, but these measuring meters do not have any control interface connected to computers to provide an automated measurement, so that these measuring meters are not practically feasible for the current measurement of the large number of electronic products in production lines.

With reference to FIG. 1 for a conventional current measurement system used for measuring the current of each of the electronic products in a production line, the current measurement system 2 receives a current I1 generated by each of the electronic products, and a linear computation circuit 4 is provided for transforming the current I1 to a voltage V, and an analog/digital conversion unit 6 is provided for converting the voltage V to a voltage V′ in a digital format to allow the processing unit 8 to perform digital processing, and finally the processing unit 8 calculates the voltage V′ and transforms the voltage V′ to a current value IV according to a resistance value of the linear computation circuit 4, and the computer terminal 10 displays the current value IV. Therefore, the current measurement of a large number of electronic products can be achieved in the production lines by repeating the aforementioned operation.

However, the conventional current measurement system 2 may receive noise signals accompanied with the current I1 in addition to the receipt of the current I1 during the process of receiving the current I1, and thus the current measurement system 2 still cannot measure the current I1 precisely regardless of the correction made by the current measurement system 2, and the present invention provides a current measurement system to overcome the aforementioned drawbacks of the prior art.

### SUMMARY

It is a primary objective of the present invention to provide a current measurement system capable of precisely measuring a current generated by a circuit under test to improve the precision of the current measurement.

Another objective of the present invention is to provide the aforementioned current measurement system, wherein the precision of the current measurement is improved by the loss of a circuit in a compensation measuring system.

A further objective of the present invention is to provide the aforementioned current measurement system, wherein the resolution of the current measurement system depends on the ampere rating (such as milliampere rating or microampere rating of a current) of a sampling current.

Another objective of the present invention is to provide the aforementioned current measurement system, wherein analog and/or digital noises are suppressed to improve the precision of the current measurement.

To achieve the aforementioned and other objectives, the present invention provides a current measurement system for measuring a current generated by a circuit under test, and the current measurement system comprises a sampling unit, an amplifying unit, a noise suppression unit, a conversion unit, a processing unit and a memory unit. Wherein, the sampling unit sampling unit is serially coupled to the circuit under test for sampling the current and transforming the current to a first voltage; the amplifying unit is coupled to the sampling unit for amplifying the first voltage to a second voltage; the noise suppression unit is coupled to the amplifying unit for filtering an analog voltage noise in the second voltage to form a third voltage; the conversion unit is coupled to the noise suppression unit for converting the third voltage into a voltage signal in a digital format; the processing unit is coupled to the conversion unit for pre-storing a calibration linear equation, calibrating the voltage signal by the calibration linear equation, and outputting the voltage signal to form a measure signal, and the measure signal is used for indicating the current precisely; and the memory unit is coupled to the processing unit for pre-storing a gradient and a bias voltage level required by the calibration linear equation.

Compared with the prior art, the current measurement system of the present invention compensates the loss of the circuit in the measurement system by hardware and software and measures the current generated by the circuit under test precisely by reducing the interference of noises. In addition, the current measurement system of the present invention determines the maximum resolution of the whole current measurement system based on the precision of the sampling circuit (such as milliampere rating or microampere rating) of a sampling current (such as the sampling circuit comprised of a plurality of resistor groups).

### BRIEF DESCRIPTION OF THE DRAWINGS

FIG. 1 is a schematic block diagram of a conventional current measurement system;

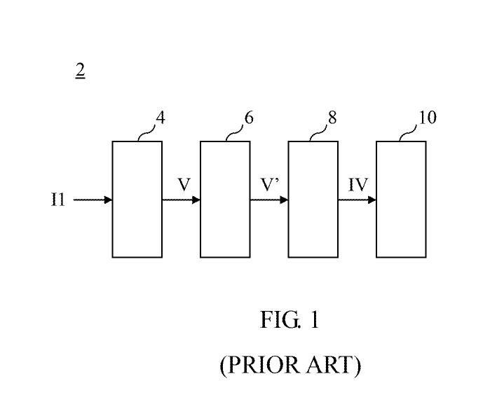

FIG. 2 is a schematic block diagram of a current measurement system in accordance with a first preferred embodiment of the present invention;

FIG. 3 is a schematic view of details of a sampling unit as depicted in FIG. 2;

FIG. 4 is a schematic view of details of an amplifying unit as depicted in FIG. 2;

FIG. 5 is a schematic view of details of a noise suppression unit as depicted in FIG. 2; and

FIG. 6 is a schematic block diagram of a current measurement system in accordance with a second preferred embodiment of the present invention.

### DETAILED DESCRIPTION

The objects, characteristics and effects of the present invention will become apparent with the detailed description of the preferred embodiments and the illustration of related drawings as follows.

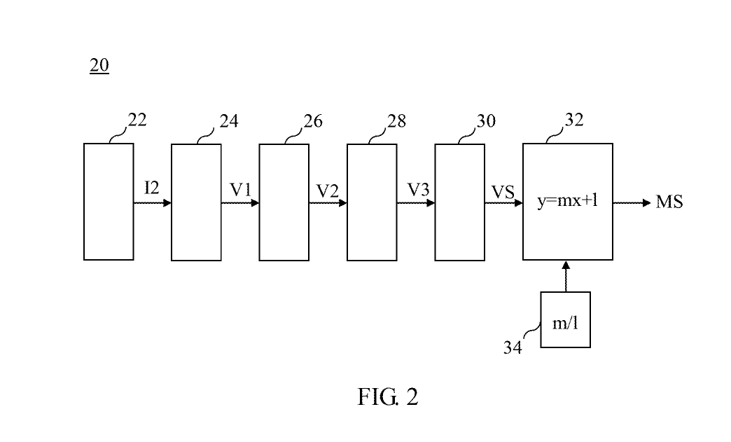

With reference to FIG. 2 for a schematic block diagram of a current measurement system in accordance with the first preferred embodiment of the present invention, the current measurement system 20 is provided for measuring a current 12 generated by a circuit under test 22 such as a circuit comprised of resistors, capacitors, inductors or integrated circuits.

Wherein, the current measurement system 20 comprises a sampling unit 24, an amplifying unit 26, a noise suppression unit 28, a conversion unit 30, a processing unit 32 and a memory unit 34.

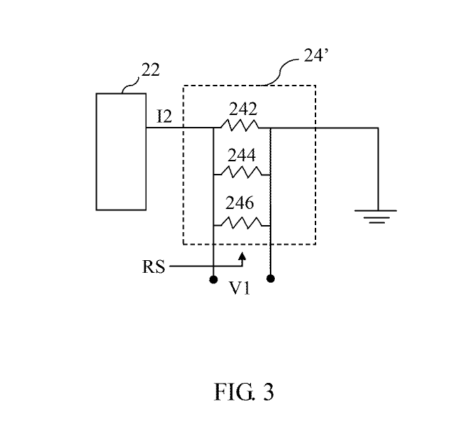

The sampling unit 24 is serially coupled to the circuit under test 22. Wherein, the sampling unit 24 obtains the current 12 from the circuit under test 22 and transforms the current 12 to a first voltage V1. For example, the first voltage V1 falls within a range between 1 mV and 50 mV, and the total resistance value of the circuit falls within a range between 1 ohm and 1 milliohm. In FIG. 3, a resistor group 24′ is used as an example of the sampling unit 24 for the illustration purpose, and the resistor group 24′ includes a plurality of shunt resistors 242, 244, 246, and the shunt resistors are connected in parallel to one another, so that the shunt resistors 242, 244, 246 form an equivalent resistance RS, and the first voltage V1 is equal to the product of the current 12 and the equivalent resistance RS. In addition, the shunt resistors can be connected by a series connection or a series-parallel connection.

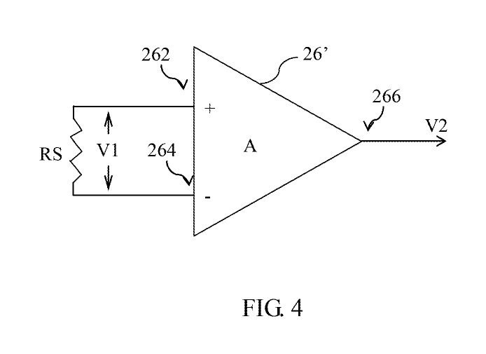

In FIG. 2, the amplifying unit 26 is coupled to the sampling unit 24 for amplifying the first voltage V1 to a second voltage V2, the amplifying unit 26 is a voltage operational amplifier 26′ as shown in FIG. 4. Wherein, the voltage operational amplifier 26′ includes a first positive voltage input terminal 262, a first negative voltage input terminal 264 and a first output terminal 266. The first positive voltage input terminal 262 is coupled to an end of the equivalent resistor RS and the first negative voltage input terminal 264 is coupled to the other end of the equivalent resistor RS, and the voltage operational amplifier 26′ provides a magnification A, so that the first voltage V1 can be amplified by the voltage operational amplifier 26′ by the magnification A into the second voltage V2. In other words, the ratio of the second voltage V2 to the first voltage V1 is equal to the magnification A.

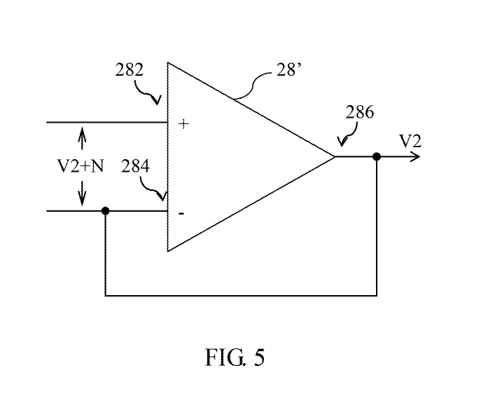

In FIG. 2, the noise suppression unit 28 is coupled to the amplifying unit 26 and provided for filtering an analog voltage noise N in the second voltage V2 to form a third voltage V3. With reference to FIG. 5, the noise suppression unit 28 is a rail-to-rail operational amplifier 28′. Wherein, the rail-to-rail operational amplifier 28′ is defined as an operational amplifier that outputs a voltage equal to the voltage supply VS supplied by the operational amplifier and features a low distortion, a low noise, a high bandwidth gain and a power-saving effect. In addition, the operational amplifier 28′ includes a second positive voltage input terminal 282, a second negative voltage input terminal 284 and a second output terminal 286. The second positive voltage input terminal 282 is coupled to the first output terminal 266 for receiving the second voltage V2, and the second negative voltage input terminal 284 is coupled to the second output terminal 286 for forming a negative feedback circuit. Since the second voltage V2 and the analog voltage noise N are amplified by the operational amplifier 28′ and the analog voltage signal N generally has a voltage level higher than the voltage level of the second voltage V2, therefore the voltage of the analog voltage signal N exceeds the voltage supply VS after the analog voltage signal N is amplified, and the output of the second output terminal 286 approaches the second voltage V2. In other words, the analog voltage signal N is suppressed indirectly.

In FIG. 2, the conversion unit 30 is coupled to the noise suppression unit 28 for converting the third voltage V3 into a voltage signal VS in a digital format. Wherein, the conversion unit 30 is an analog-to-digital converter.

The processing unit 32 is coupled to the conversion unit 30 for pre-storing a calibration linear equation. The processing unit 32 calibrates the voltage signal VS and turns the outputted voltage signal VS into a measure signal MS, wherein the measure signal MS indicates a precise measurement of the current 12.

The calibration linear equation is given below:

y=mx+l,

wherein, “m” is the gradient, “l” is the bias voltage level, “x” is the voltage signal VS and “y” is the measure signal MS.

Further, the memory unit 34 is coupled to the processing unit 32 for pre-storing a gradient and a bias voltage level required by the calibration linear equation. Wherein, m stands for the gradient and l stands for the bias voltage level.

In another preferred embodiment, although the voltage signal VS is processed by the noise suppression unit 28 to suppress the analog voltage noise N, yet there is still a small portion of noises that are not filtered. Therefore, the processing unit 32 further includes a digital filtering algorithm (such as median filtering), and the digital filtering algorithm is provided for filtering a digital noise produced by the voltage signal VS and/or the measure signal MS. Wherein, the digital noise is defined as a signal that cannot be filtered after the analog voltage noise N is converted by the conversion unit 30, and the digital noise exists in the voltage signal VS or the measure signal MS.

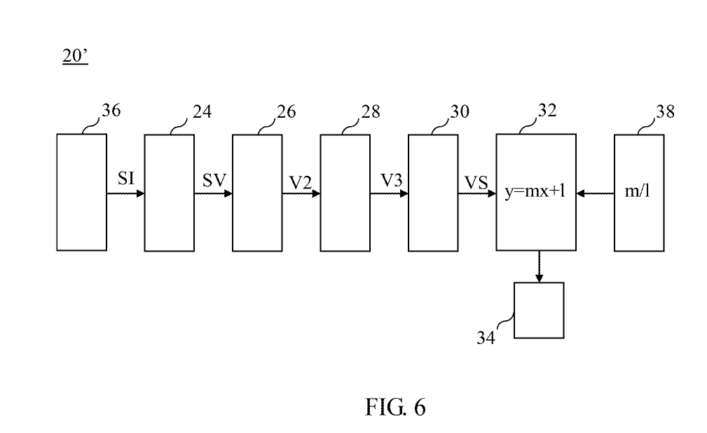

With reference to FIG. 6 for a schematic block diagram of a current measurement system in accordance with the second preferred embodiment of the present invention, the current measurement system 20′ further comprises a standard current generating unit 36 and a computer terminal unit 38 in addition to the sampling unit 24, the amplifying unit 26, the noise suppression unit 28, the conversion unit 30, the processing unit 32 and the memory unit 34 as described in the first preferred embodiment.

Wherein, the standard current generating unit 36 generates a standard current SI. By the connection of the standard current generating unit 36 to the sampling unit 24, the sampling unit 24 transforms the standard current SI to a standard voltage SV, and the standard voltage SV is processed by the amplifying unit 26, the noise suppression unit 28, the conversion unit 30 and the processing unit 32 and used for outputting the measure signal MS from the processing unit 32.

The computer terminal unit 38 is coupled to the processing unit 30 and the memory unit 34. Wherein, the computer terminal unit 38 has a built-in least-squares algorithm (that receives a plurality of standard currents SI to calculate the mean of the standard currents SI) provided for calculating the measure signal MS and solving the gradient m and the bias voltage level l, and the computer terminal unit 38 saves the gradient m and the bias voltage level l into the memory unit 34.

Further, the mathematical equations of the least-squares algorithm used for calculating the gradient m and the bias voltage level l are given below:

m=(nΣᵢ₌₁ⁿxᵢyᵢ−Σᵢ₌₁ⁿxᵢΣᵢ₌₁ⁿyᵢ)/(nΣᵢ₌ⁿxᵢ²−(Σᵢ₋ₐⁿxᵢ)² ; and l=\dot{y}−m\dot{x};

Wherein, “m” is the gradient, “l” is the bias voltage level, “x” is the voltage signal, “y ” is the measure signal, “\dot{x}” is the mean of “x” and “\dot{y}” is the mean of “y”.

In addition, the computer terminal unit 38 also has a built-in correlation coefficient algorithm or a linear regression algorithm used for determining the linearity between the measure signal MS and the voltage signal VS. After the result of the linearity is normalized (to range between −1 and 1), the current measurement system 20′ can make decision based on the normalized result.

For example, if the linearity is in the neighborhood of “1” which is called a positive correlation or “−1” which is called a negative correlation (such as −1<normalized linearity≦−0.99 or 0.99≦normalized linearity<1), it indicates a good linearity between the input and the output of the linear measurement system. The following linear regression method can be used for calibrating the output of the linear measurement system (which is the value measured by the linear system) to optimize the linearity of the linear measurement system, so that the linear measurement system can provide a precise linear measurement. On the other hand, if the linearity is far away from “1” or “−1” (such as −0.99<normalized linearity<0.99), it indicates that the current measurement system 20′ provides a poor linearity and cannot achieve a precise linear measurement by means of the calibration. If the linearity is equal to “1” or “−1”, it indicates that the current measurement system 20′ is precise and requires no calibration. In other words, if the normalized linearity is equal to “1” or “−1”, or smaller than “0.99” and greater than “−0.99”, the linear equation to be used as a calibration equation is not necessary.

Further, the mathematical equations of the correlation coefficient algorithm used for calculating the linearity is given below:

(Σ(x−\dot{x})(y−\dot{y}))/(\sqrt{Σ(x−\dot{x})²}\sqrt{Σ(y−\dot{y})²})

Wherein,

\dot{x}Σᵢ₌₁ⁿxᵢ/n; \dot{y}=Σᵢ₌₁ⁿyᵢ/n.

Wherein, “x” is the value of the voltage signal VS, “y” is the measure signal MS, “\dot{x}” is the mean of “x”, “\dot{y}” is the mean of “y” and “n” is a natural number.

Therefore, the current measurement system of the present invention can compensate the loss of a circuit of the measurement system by hardware and software and reduce the noise interference to precisely measure the current generated by circuit under test. In addition, the current measurement system of the present invention can determine the maximum resolution of the whole current measurement system based on the precision of the current sampled by the sampling circuit.

While the invention has been described by means of specific embodiments, numerous modifications and variations could be made thereto by those skilled in the art without departing from the scope and spirit of the invention set forth in the claims.

What is claimed is:

1. A current measurement system, for measuring a current generated by a circuit under test, comprising:
a sampling unit, serially coupled to the circuit under test, for sampling the current and transforming the current to a first voltage;
an amplifying unit, coupled to the sampling unit, for amplifying the first voltage to a second voltage;
a noise suppression unit, coupled to the amplifying unit, for filtering an analog voltage noise in the second voltage to form a third voltage;
a conversion unit, coupled to the noise suppression unit, for converting the third voltage into a voltage signal of a digital format;
a processing unit, coupled to the conversion unit, for pre-storing a calibration linear equation, calibrating the voltage signal by the calibration linear equation, and outputting the voltage signal to form a measure signal, and the measure signal being used for indicating the current precisely; and
a memory unit, coupled to the processing unit, for pre-storing a gradient and a bias voltage level required by the calibration linear equation.

2. The current measurement system of claim 1, wherein the sampling unit is a resistor group having a plurality of shunt resistors, and the shunt resistors are coupled by a series connection, a parallel connection, or a series-parallel connection, and the resistor group generates the first voltage by the current and supplies the first voltage to the amplifying unit to amplify the first voltage to the second voltage.

3. The current measurement system of claim 2, wherein the first voltage falls within a range between 1 mV and 50 mV, and the resistor group has an equivalent resistance value falling within a range between 1 ohm and 1 milliohm.

4. The current measurement system of claim 1, wherein the amplifying unit is a voltage operational amplifier, and the noise suppression unit is a rail-to-rail operational amplifier.

5. The current measurement system of claim 1, wherein the calibration linear equation is expressed as y=mx+l , wherein “m” is the gradient, “l” is the bias voltage level, “x” is the voltage signal and “y” is the measure signal.

6. The current measurement system of claim 5, further comprising a standard current generating unit coupled to the sampling unit for transforming a standard current to a standard voltage, and the standard voltage being processed by the amplifying unit, the noise suppression unit, the conversion unit and the processing unit to output the measure signal from the processing unit.

7. The current measurement system of claim 6, further comprising a computer terminal unit coupled to the processing unit and the memory unit, and the computer terminal unit having a built-in least-squares algorithm for calculating the measure signal and solving the gradient and the bias voltage level, and the computer terminal unit saving the gradient and the bias voltage level into the memory unit.

8. The current measurement system of claim 7, wherein the gradient and the bias voltage level are calculated by m=(nΣᵢ₌₁ⁿxᵢyᵢ−Σᵢ₌₁ⁿxᵢΣᵢ₌₁ⁿxᵢΣᵢ₌₁ⁿyᵢ)/(nΣᵢ₌₁ⁿxᵢ²−(Σᵢ₌₁ⁿxᵢ)²); and l=\dot{y}−m\dot{x} respectively, and “m” is the gradient, “l” is the bias voltage level, “x” is the voltage signal, “y” is the measure signal, “\dot{x}” is the mean of “x”, and “\dot{y}” is the mean of “y”.

9. The current measurement system of claim 1, wherein the processing unit further includes a digital filtering algorithm for filtering a digital noise produced by at least one of the voltage signal and the measure signal.

10. The current measurement system of claim 9, wherein the digital filtering algorithm is a median filtering method.
